(19) United States
(12) Patent Application Publication
(10) Pub. No.: US 2024/0047284 A1
(43) Pub. Date: Feb. 8, 2024

(54) COMPOSITE SUBSTRATE AND SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/361,490

(22) Filed: Jul. 28, 2023

(30) Foreign Application Priority Data
Aug. 3, 2022 (CN) 202222031569.7

(51) Int. Cl. H01L 23/13; H01L 23/473; H01L 23/492; H01L 23/14

(52) U.S. Cl. CPC H01L 23/13; H01L 23/473; H01L 23/4926; H01L 23/147

(57) ABSTRACT

Disclosed are a composite substrate and a semiconductor structure, and the composite substrate includes a first semiconductor layer and a second semiconductor layer that are stacked, at least one heat dissipation groove is disposed on a surface, close to the second semiconductor layer, of the first semiconductor layer, a heat dissipation channel is disposed on a side wall of the first semiconductor layer, or a surface, away from the second semiconductor layer, of the first semiconductor layer, and the heat dissipation channel is in communication with the heat dissipation groove. The composite substrate and the semiconductor structure according to the present application can effectively resolve a heat dissipation problem of a high-power gallium nitride-based component by using a heat dissipation channel and a heat dissipation groove that are interconnected internal and external.

### CROSS-REFERENCE TO RELATED APPLICATIONS

This present application claims priority to Chinese Patent Application No. 202222031569.7, filed on Aug. 3, 2022, which is hereby incorporated by reference in its entirety.

### TECHNICAL FIELD

The present disclosure relates to the field of semiconductor technologies, and in particular to a composite substrate and a semiconductor structure.

### BACKGROUND

As a representative material of a third-generation semiconductor, gallium nitrides have many advantages such as high mobility, high critical electric field, and high luminous efficiency, and are widely used in various fields such as semiconductor lighting, radio frequency power amplifier, and power electronics.

Materials of substrates for epitaxial growth of gallium nitride-based materials main include gallium nitride, silicon carbide, sapphire, silicon, and the like. A homogeneous epitaxy of gallium nitride substrates is the best choice for epitaxy of gallium nitride materials because there are no problems such as lattice mismatch or thermal mismatch. However, because gallium nitride substrates has low applicability as commercial gallium nitride substrates due to their high price, difficulty in preparation, and a fact that large-sized wafers cannot be prepared in batches at present; silicon carbide substrates have advantages, such as high critical electric field and high thermal conductivity, similar to gallium nitride, but costs are still relatively high; sapphire substrates are cheap, but their heat dissipation performances are poor, and are only used in low-power and low-frequency components; but silicon substrates are rich in output, mature in technology, low in costs, and compatible with a traditional CMOS process, it is considered that the silicon substrates are the most potential substrates for epitaxial growth of gallium nitride-based materials in business. However, low thermal conductivity of silicones and poor heat dissipation performance of silicon-based components seriously affect a performance and a life of devices.

To reduce an epitaxy cost of a gallium nitride-based material, a relatively low-cost substrate such as silicon or sapphire is preferred, but a heat dissipation capability of the substrate becomes an urgent problem to be solved. In a conventional manner, the heat dissipation capability is improved in a manner of thinning a substrate or optimizing encapsulation. However, thinning a substrate generally reduces a hardness of the substrate, and after epitaxy, the substrate is prone to warping, and a process of optimizing encapsulation is cumbersome, resulting in a reduction in production efficiency.

### SUMMARY

A purpose of the present application is to provide a composite substrate and a semiconductor structure with a high heat dissipation capability.

According to an aspect of the present application, a composite substrate is provided, including: a first semiconductor layer and a second semiconductor layer that are stacked, where at least one heat dissipation groove is disposed on a surface, close to the second semiconductor layer, of the first semiconductor layer, a heat dissipation channel is disposed on a side wall of the first semiconductor layer, or a surface, away from the second semiconductor layer, of the first semiconductor layer, and the heat dissipation channel is in communication with the heat dissipation groove.

As an optional embodiment, the heat dissipation channel includes a first channel and a second channel that are respectively in communication with two ends of the heat dissipation groove.

As an optional embodiment, a shape of a horizontal cross-section of the at least one heat dissipation groove includes one or a combination of a rectangle, a square, a circle, and a hexagonal, and the horizontal cross-section is parallel to the surface, close to the second semiconductor layer, of the first semiconductor layer.

As an optional embodiment, the composite substrate further includes a bonding layer located between the first semiconductor layer and the second semiconductor layer.

As an optional embodiment, a material of the first semiconductor layer includes one or a combination of Si, Al₂O₃, SiC, and GaN.

As an optional embodiment, a passivation structure covers on an inner wall of the heat dissipation groove and/or the heat dissipation channel.

As an optional embodiment, the first semiconductor layer further includes a third channel, the at least one heat dissipation groove includes a plurality of heat dissipation grooves, and the third channel is in communication with the plurality of the heat dissipation grooves.

As an optional embodiment, a width of the heat dissipation groove is constant, gradually decreased, or gradually increased in a direction from the first semiconductor layer to the second semiconductor layer.

As an optional embodiment, a width of a shape of a horizontal cross-section of the heat dissipation groove is gradually decreased from a center to two ends, and the horizontal cross-section is parallel to the surface, close to the second semiconductor layer, of the first semiconductor layer.

As an optional embodiment, a material of the second semiconductor layer includes one or a combination of Si, Al₂O₃, SiC, and GaN.

As an optional embodiment, the second semiconductor layer includes a nitride semiconductor structure, and a surface, away from the first semiconductor layer, of the second semiconductor layer is a Nitrogen-plane.

As an optional embodiment, a thickness of the second semiconductor layer is not greater than a thickness of the first semiconductor layer.

As an optional embodiment, the composite substrate further includes a circulating coolant disposed in the heat dissipation groove.

As an optional embodiment, the first semiconductor layer includes a central region and an edge region, the at least one heat dissipation groove includes a plurality of heat dissipation grooves, and a distribution density of heat dissipation grooves in the central region is greater than a distribution density of heat dissipation grooves in the edge region.

As an optional embodiment, a heat dissipation cavity, corresponding to the heat dissipation groove of the first semiconductor layer, is disposed in the second semiconductor layer, the heat dissipation cavity forms a gradually closed top in an epitaxial manner, and the heat dissipation cavity and the heat dissipation groove are in communication with each other to form a heat dissipation space.

According to another aspect of the present application, a semiconductor structure is provided, including: a composite substrate described above; a channel layer and a barrier layer that are sequentially located on the composite substrate; and a source, a gate and a drain that are located on the barrier layer. The source and the drain are respectively located on two sides of the gate.

A composite substrate and a semiconductor structure provided in the present application can effectively resolve a heat dissipation problem of a high-power gallium nitride-based component by using a heat dissipation channel that is interconnected internal and external.

### BRIEF DESCRIPTION OF THE DRAWINGS

FIG. 1 is a schematic structural diagram of a composite substrate according to an embodiment of the present application.

FIG. 2 is a schematic sectional view taken along line PP′ in FIG. 1.

FIG. 3 is a schematic top view of a first semiconductor layer according to an embodiment of the present application.

FIG. 4 is schematic structural diagram of a composite substrate according to another embodiment of the present application.

FIG. 5 is a schematic top view of a first semiconductor layer according to another embodiment of the present application.

FIG. 6 is a schematic sectional view taken along line AA′ in FIG. 5.

FIG. 7 is schematic structural diagram of a composite substrate according to another embodiment of the present application.

FIG. 8 is schematic structural diagram of a composite substrate according to another embodiment of the present application.

FIG. 9 is a schematic top view of a first semiconductor layer according to another embodiment of the present application.

FIG. 10 is schematic structural diagram of a composite substrate according to another embodiment of the present application.

FIG. 11 is schematic structural diagram of a semiconductor structure according to an embodiment of the present application.

FIG. 12 is a schematic top view of a first semiconductor layer according to another embodiment of the present application.

FIG. 13 is a schematic top view of a first semiconductor layer according to another embodiment of the present application.

### DETAILED DESCRIPTION OF THE EMBODIMENTS

Exemplary embodiments will be described herein in detail, the embodiments of which are shown in the accompanying drawings. Following description relates to the accompanying drawings, unless otherwise indicated, same numbers in different accompanying drawings represent a same or similar elements. The embodiments described in following example implementations do not represent all implementations consistent with the present application. On the contrary, they are merely examples of devices consistent with some aspects of the present application as detailed in the appended claims.

### Embodiment 1

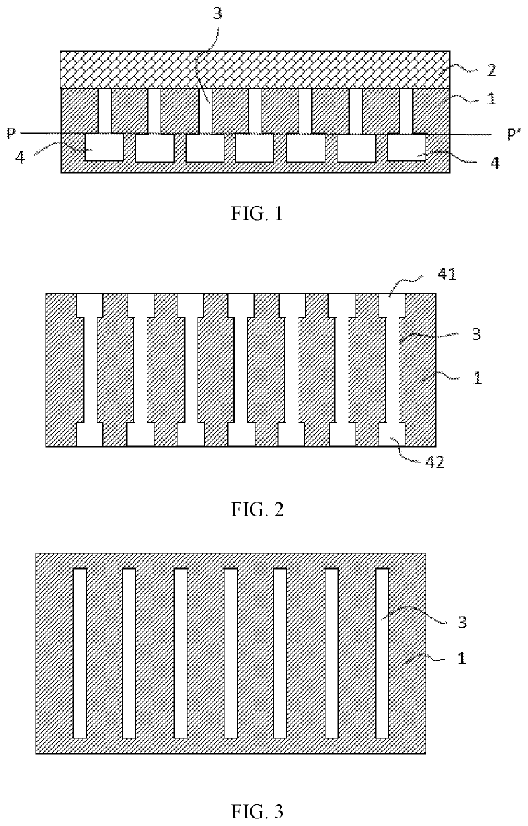

As shown in FIG. 1, an embodiment of the present application discloses a composite substrate, including: a first semiconductor layer 1 and a second semiconductor layer 2 that are stacked. At least one heat dissipation groove 3 is disposed on a surface, close to the second semiconductor layer 2, of the first semiconductor layer 1. A heat dissipation channel 4 is disposed on a side wall of the first semiconductor layer 1, or a surface, away from the second semiconductor layer 2, of the first semiconductor layer 1. The heat dissipation channel 4 is in communication with the heat dissipation groove 3.

According to the composite substrate provided in the embodiment, the heat dissipation groove 3 inside the first semiconductor layer 1 communicates with the heat dissipation channel 4 on a side wall or a bottom of the first semiconductor layer 1 to form a heat dissipation flow channel that is interconnected internal and external, so as to effectively dissipate heat from a component formed on the second semiconductor layer 2, thereby improving a life of the component. In addition, the structure is simple and efficient, and is conducive to large-scale commercial production.

Furtherly, as shown in FIG. 2, FIG. 2 is a schematic sectional view taken along line PP′ in FIG. 1, the heat dissipation channel 4 includes a first channel 41 and a second channel 42 that are respectively in communication with two ends of the heat dissipation groove 3, so as to form a circulating flow channel that is interconnected internal and external, thereby further enhancing a heat dissipation capability. In another embodiment, referring to FIG. 13, only one first channel 41 and/or one second channel 42 may be disposed to be respectively in communication with two ends of a plurality of the heat dissipation channels 4, that is, ends, located on one side, of the plurality of the heat dissipation channels 4 are in communication with each other, and then communicate with one first channel 41 or one second channel 42. In this way, only one first channel 41 and/or one second channel 42 may be disposed on a sidewall of the first semiconductor layer 1, thereby effectively simplifying a preparation difficulty and a preparation cost of a composite substrate and greatly improving a production efficiency.

In an embodiment, as shown in FIG. 3, FIG. 3 is a schematic top view of a first semiconductor layer 1 according to an embodiment of the present application. A cross-sectional shape of the heat dissipation groove 3 includes a rectangle. In another embodiment, the cross-sectional shape of the heat dissipation groove 3 may further include one or a combination of a square, a circle, and a hexagon. The cross-sectional shape is parallel to a surface, close to the second semiconductor layer 2, of the first semiconductor layer 1. Preferably, the cross-sectional shape of the heat dissipation groove 3 is disposed in a rectangular shape, and a plurality of the heat dissipation grooves 3 are distributed in the first semiconductor layer 1 in parallel at a certain spacing, so as to further enhance a heat dissipation capability of a subsequently grown component.

In an embodiment, a material of the first semiconductor layer 1 includes one or a combination of Si, Al₂O₃, SiC or GaN. A material of the second semiconductor layer 2 includes one or a combination of Si, Al₂O₃, SiC or GaN. In another embodiment, the second semiconductor layer 2 may include a group III nitride semiconductor structure. Optionally, a surface, away from the first semiconductor layer 1, of the second semiconductor layer 2 may be a N (nitrogen) surface, so as to improve crystal quality of subsequent epitaxial growth of a GaN-based material and improve performance of a subsequently prepared GaN-based component.

Optionally, a thickness of the second semiconductor layer 2 is not greater than a thickness of the first semiconductor layer 1. In an optional embodiment, the second semiconductor layer 2 may be a thin film, or may be close to a thickness of the first semiconductor layer 1, so as to ensure a heat dissipation effect of the composite substrate.

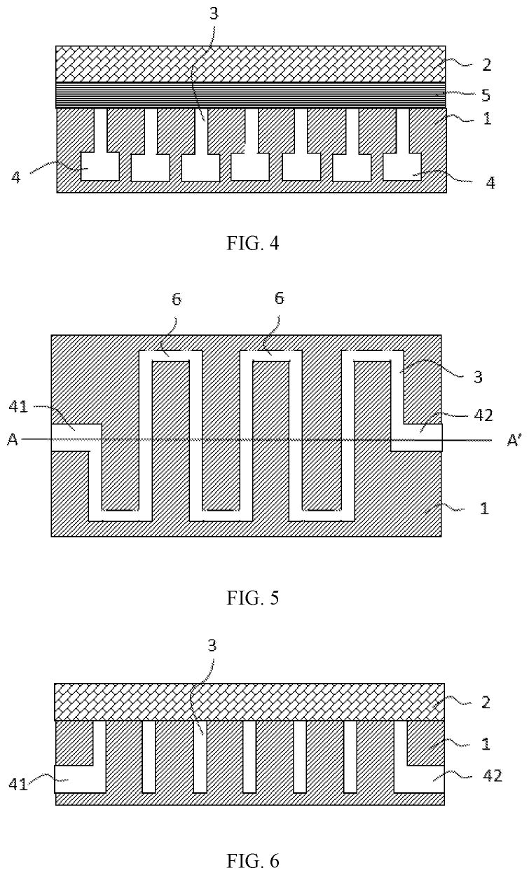

In an embodiment of the present application, as shown in FIG. 4, FIG. 4 is schematic structural diagram of a composite substrate according to another embodiment of the present application, the second semiconductor layer 2 may be formed above the first semiconductor layer 1 by using a bonding process, and the composite substrate may further include a bonding layer 5 located between the first semiconductor layer 1 and the second semiconductor layer 2. When the material of the first semiconductor layer 1 is Si (111) and the material of the second semiconductor layer is Si (100), the material of the bonding layer 5 is SiO₂, in this way, the composite substrate is formed as a SOI (Silicon-On-Insulator) substrate with a heat dissipation flow channel, thereby effectively resolving a heat dissipation problem of the SOI substrate structure. Optionally, the second semiconductor layer 2 is disposed on the first semiconductor layer 1 in an epitaxial manner, and the first semiconductor layer 1 is a supporting structure having a plurality of heat dissipation grooves 3. The second semiconductor layer 2 is disposed on the first semiconductor layer 1 having the plurality of heat dissipation grooves in a lateral epitaxial manner. Because the epitaxial growth is a time-related process, the second semiconductor layer 2 cannot immediately synthesize a plane after growth starts, a heat dissipation cavity, corresponding to the heat dissipation groove of the first semiconductor layer 1, is disposed in the second semiconductor layer. The heat dissipation cavity forms a gradually closed top in an epitaxial manner, and the heat dissipation cavity and the heat dissipation groove are connected to each other to form a heat dissipation space with a closed top.

### Embodiment 2

Embodiment 2 and Embodiment 1 are approximately a same structure, and a same part is not described again. As shown in FIG. 5 and FIG. 6, FIG. 6 is a schematic sectional view taken along line AA′ in FIG. 5. A difference point merely is that the first semiconductor layer 1 further includes a third channel 6, a plurality of heat dissipation grooves 3 are in communication with the third channel 6, and form a complete heat dissipation flow channel with a first channel 41 and a second channel 42. The third channel 6 and the heat dissipation groove 3 may be fabricated by means of synchronous processing. In this embodiment, just one first channel 41 and one second channel 42 need to be disposed to connect all heat dissipation grooves 3 in the first semiconductor layer 1, thereby effectively reducing production costs of the composite substrate.

### Embodiment 3

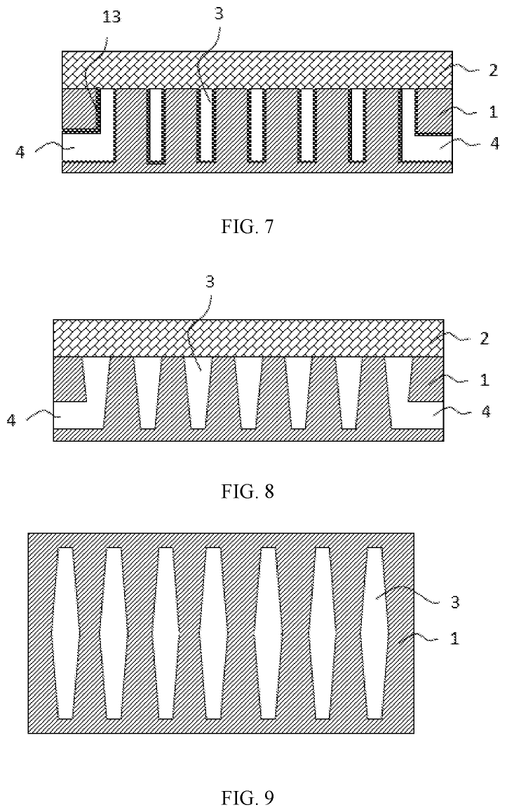

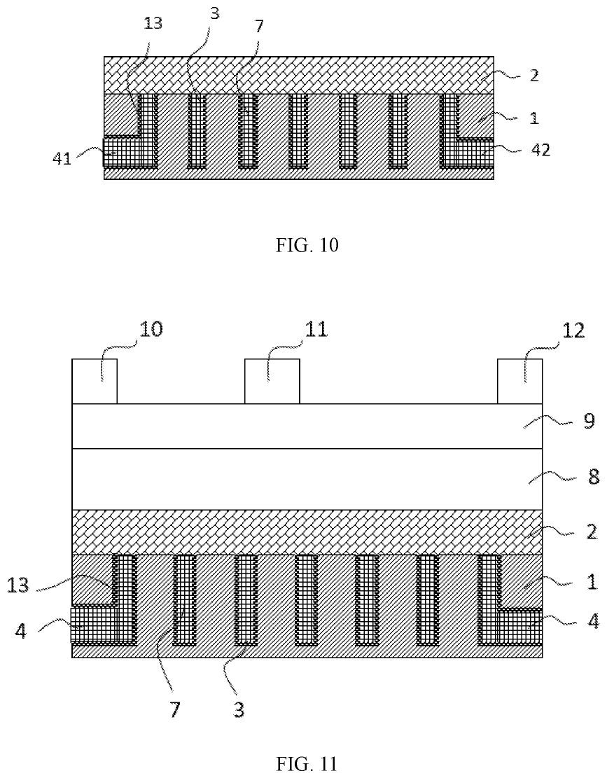

Embodiment 3 and Embodiment 1 or Embodiment 2 are approximately a same structure, and a same part is not described again. As shown in FIG. 7, further, a passivation structure 13 covers on an inner wall of the heat dissipation groove 3 and/or the heat dissipation channel 4, so as to further ensure a stability of the first semiconductor layer 1. In this embodiment, further referring to FIG. 10, the composite substrate further includes a circulating coolant 7 disposed in the heat dissipation groove 3. The first channel 41 is an inlet of the coolant 7, and the second channel 42 is an outlet of the coolant 7. By setting the circulating coolant 7 inside a first substrate 1, a heat dissipation capability of the composite substrate can be further increased. The passivation structure 13 disposed in this embodiment can also prevents the coolant 7 from causing corrosion damage to the first substrate 1, which is not limited in the present application.

### Embodiment 4

Embodiments 4 and any one of the Embodiments 1 to 3 are approximately a same structure, and a same part is not described again. A difference is merely that, a width of the heat dissipation groove 3 is constant, gradually decreased, or gradually increased from bottom to top, in a direction from the first semiconductor layer 1 to the second semiconductor layer 2. As shown in FIG. 8, in the direction from the first semiconductor layer 1 to the second semiconductor layer 2, a width of the heat dissipation groove 3 gradually increases, so as to increase a contact area between the heat dissipation groove 3 and the second semiconductor layer 2, and further improve a heat dissipation capability. In another embodiment, a width of the heat dissipation groove 3 may also be in another variation manner, which is not limited herein in this embodiment.

### Embodiment 5

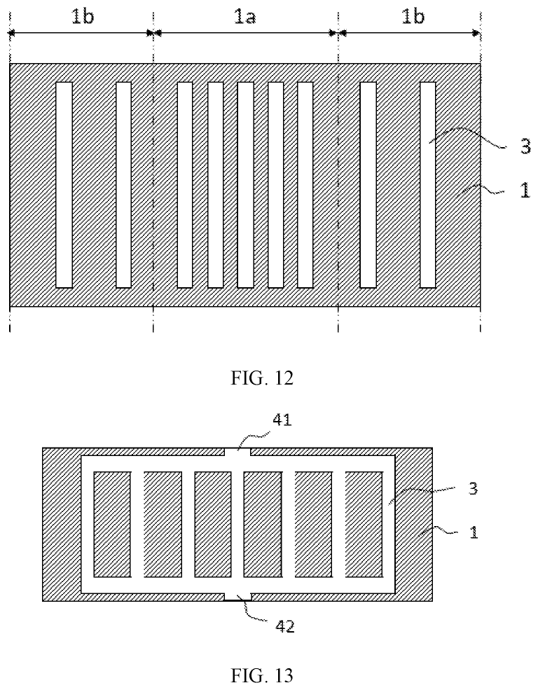

Embodiment 5 and any one of the Embodiments 1 to 4 are approximately a same structure, and a same part is not described again. As shown in FIG. 9, FIG. 9 is a schematic top view of a first semiconductor layer according to another embodiment of the present application. A difference point is merely that a width of a shape of a horizontal cross-section of the heat dissipation groove 3 is gradually decreased from a center to two ends, and the horizontal cross-section is parallel to the surface, close to the second semiconductor layer 2, of the first semiconductor layer 1. Due to a relatively high central temperature of a device, a width of a shape of a horizontal cross-section of the heat dissipation groove 3 gradually decreases from a center to two ends to further ensure uniformity of heat dissipation of the device. In another optional embodiment, furtherly referring to FIG. 12, FIG. 12 is a schematic top view of a first semiconductor layer according to another embodiment of the present application, a heat dissipation uniformity may further be adjusted by using a distribution density of the heat dissipation groove 3 in the first semiconductor layer 1. For example, heat dissipation grooves 3 located in a center region 1a of the first semiconductor layer 1 is relatively dense, and heat dissipation grooves 3 located in an edge region 1b of the first semiconductor layer 1 is relatively sparse, thereby improving a heat dissipation capability of a center of a subsequently prepared device.

### Embodiment 6

The embodiment discloses a semiconductor structure. As shown in FIG. 11, the semiconductor structure includes a composite substrate according to any one of Embodiment 1 to Embodiment 5, a channel layer 8 and a barrier layer 9 that are sequentially formed on the composite substrate, and a source 10, a gate 11 and a drain 12 that are located on the barrier layer 9. The source 10 and the drain 12 are respectively located on two sides of the gate 11. A semiconductor structure prepared by using the foregoing composite substrate can effectively resolve a heat dissipation problem of a high-power component, improve a breakdown voltage, and increase a service life.

The foregoing descriptions are merely preferred embodiments of the present application, and are not intended to limit the present application in any form. Although the present application has been disclosed in a better embodiment as above, it is not intended to limit the present application. any person skilled in the art may make a slight change or modify the technical content disclosed above to an equivalent implementation of an equivalent change without departing from a scope of the technical solution of the present application. However, any modification, equivalent change, or modification of the foregoing implementation according to the essential technology of the present application falls within the scope of the present application.

What is claimed is:

1. A composite substrate, comprising:
a first semiconductor layer and a second semiconductor layer that are stacked,
wherein at least one heat dissipation groove is disposed on a surface, close to the second semiconductor layer, of the first semiconductor layer, a heat dissipation channel is disposed on a side wall of the first semiconductor layer, or a surface, away from the second semiconductor layer, of the first semiconductor layer, and the heat dissipation channel is in communication with the heat dissipation groove.

2. The composite substrate according to claim 1, wherein the heat dissipation channel comprises a first channel and a second channel that are respectively in communication with two ends of the heat dissipation groove.

3. The composite substrate according to claim 1, wherein a shape of a horizontal cross-section of the at least one heat dissipation groove comprises one or a combination of a rectangle, a square, a circle, and a hexagonal, and the horizontal cross-section is parallel to the surface, close to the second semiconductor layer, of the first semiconductor layer.

4. The composite substrate according to claim 1, further comprising:
a bonding layer located between the first semiconductor layer and the second semiconductor layer.

5. The composite substrate according to claim 1, wherein a material of the first semiconductor layer comprises one or a combination of Si, Al₂O₃, SiC, and GaN.

6. The composite substrate according to claim 1, wherein a passivation structure covers on an inner wall of the heat dissipation groove and/or the heat dissipation channel.

7. The composite substrate according to claim 1, wherein the first semiconductor layer further comprises a third channel, the at least one heat dissipation groove comprises a plurality of heat dissipation grooves, and the third channel is in communication with the plurality of the heat dissipation grooves.

8. The composite substrate according to claim 1, wherein a width of the heat dissipation groove is constant, gradually decreased, or gradually increased in a direction from the first semiconductor layer to the second semiconductor layer.

9. The composite substrate according to claim 1, wherein a width of a shape of a horizontal cross-section of the heat dissipation groove is gradually decreased from a center to two ends, and the horizontal cross-section is parallel to the surface, close to the second semiconductor layer, of the first semiconductor layer. The composite substrate according to claim 1, wherein a material of the second semiconductor layer comprises one or a combination of Si, Al₂O₃, SiC, and GaN.

11. The composite substrate according to claim 1, wherein the second semiconductor layer comprises a nitride semiconductor structure, and a surface, away from the first semiconductor layer, of the second semiconductor layer is a Nitrogen-plane.

12. The composite substrate according to claim 1, wherein a thickness of the second semiconductor layer is not greater than a thickness of the first semiconductor layer.

13. The composite substrate according to claim 1, further comprising:
a circulating coolant disposed in the heat dissipation groove.

14. The composite substrate according to claim 1, wherein the first semiconductor layer comprises a central region and an edge region, the at least one heat dissipation groove comprises a plurality of heat dissipation grooves, and a distribution density of heat dissipation grooves in the central region is greater than a distribution density of heat dissipation grooves in the edge region.

15. The composite substrate according to claim 1, wherein a heat dissipation cavity, corresponding to the heat dissipation groove of the first semiconductor layer, is disposed in the second semiconductor layer, the heat dissipation cavity forms a gradually closed top in an epitaxial manner, and the heat dissipation cavity and the heat dissipation groove are in communication with each other to form a heat dissipation space.

16. A semiconductor structure, comprising:
the composite substrate according to claim 1;
a channel layer and a barrier layer that are sequentially located on the composite substrate; and
a source, a gate and a drain that are located on the barrier layer, wherein the source and the drain are respectively located on two sides of the gate.
